(19) United States
(12) Patent Application Publication
(10) Pub. No.: US 2007/0181993 A1
(43) Pub. Date: Aug. 9, 2007

(54) Printed circuit board including reinforced copper plated film and method of fabricating the same

(75) Inventors: Jae-Hoon Choi, Cheonan-si (KR); Kwang-Su Yu, Cheonan-si (KR); Hyo-Jae Bang, Cheonan-si (KR); Dong-Chun Lee, Cheonan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/699,498

(22) Filed: Jan. 30, 2007

(30) Foreign Application Priority Data
Feb. 6, 2006 (KR) 10-2006-0011245

(51) Int. Cl. H01L 23/04

(52) U.S. Cl. 257/698

(57) ABSTRACT

A printed circuit board (PCB) may include a substrate. A copper layer may be formed over a portion of the substrate, the copper layer including at least one of a metallic powder and a ceramic powder.

### PRIORITY STATEMENT

This U.S. non-provisional application claims the benefit of priority to Korean Patent Application No. 10-2006-0011245, filed on Feb. 6, 2006, in the Korean Intellectual Property Office (KIPO), the disclosure of which is incorporated herein in its entirety by reference.

### BACKGROUND

1. Field

Example embodiments relate to a printed circuit board (PCB) used for a semiconductor package and a method of fabricating the same, for example, a PCB including a reinforced copper plated film and method of fabricating the same.

2. Description of the Related Art

Generally, a semiconductor chip with an integrated circuit may be mounted on a printed circuit board (PCB) to be used for an electronic product. The PCB may be formed by stacking unit substrates. Each unit substrates may include an insulating material, for example, an epoxy, coated with a laminate, for example, copper. The PCB may include a via-hole so that an electrical current may flow from a first direction to a second direction of the board. The via-hole may be coated with a copper plated film. The PCB may include a contact pad on which a joining structure, for example, a solder bump, may be formed. The contact pad may be coated with a copper plated film.

In the PCB, a copper exposed portion, for example, a via-hole or a contact pad, may be coating-processed to prevent the oxidation of the copper. For example, the coating process may be an organic solderability preservative (OSP) coating process and an electroless nickel immersion gold (ENIG) coating process. The OSP coating process may use an organic compound, for example, imidazole or azole, and the ENIG coating process may coat an electroless nickel layer with a gold layer by immersion plating. The OSP coating may not cause an environmental pollution issue because it does not include lead. However, because the mechanical integrity of a copper pattern formed by the OSP coating process may be weaker, a crack may form in the copper pattern. If a copper pattern is processed with the ENIG coating, the mechanical integrity of the cooper pattern may be stronger because it may be protected with a nickel-gold coating layer. However, as time goes by, a solder bump that may be connected to the ENIG-coated pad may separate from the pad.

In an OSP-coated PCB, because the integrity of a copper pattern may be weaker, a crack may form in a copper plated film of a via-hole. Thus, the reliability of a product containing the PCB may be deteriorated. FIG. 1 is a photograph of cracks formed in a copper plated film of a via-hole in a conventional PCB during the thermal cycling test of a semiconductor package. For example, the cracks may be formed because of the difference in thermal expansion coefficient between the insulating material and copper of the PCB. The thermal expansion coefficient of FR4, which is a type of glass epoxy that may be used as the insulating material of the PCB, is about 70×10⁻⁶/° C., and the thermal expansion coefficient of copper is about 17×10⁻⁶/° C. Because the thermal expansion coefficient of FR4 is greater than that of copper at the same temperature, the copper plated film formed on the surface of FR4 may not reach the thermal expansion extent of FR4, and thus cracks may form. If cracks form in the via-hole, the circuit may be open, and thus may prevent an electrical signal from being transferred. As a result, the reliability of a semiconductor package product may be decreased.

### SUMMARY

Example embodiments may provide a reliable printed circuit board (PCB) which may reduce or prevent a crack from forming and/or spreading in a copper plated film in a via-hole and a contact pad in a PCB using an organic solderability preservative (OSP) coating layer, and a method of fabricating the same.

In an example embodiment, a PCB may include a substrate and a copper layer formed over a portion of the substrate. The copper layer may include at least one of a metallic powder and a ceramic powder.

According to an example embodiment, the metal powder may include at least one of cobalt (Co), nickel (Ni), iron (Fe), chromium (Cr), zinc (Zn), nobelium (No), tungsten (W), vanadium (V), manganese (Mn), titanium (Ti), and tin (Sn)

According to an example embodiment, the ceramic powder may include at least one of aluminum oxide (or alumina) (Al₂O₃), silicon carbide (SiC), silicon dioxide (or silica) (SiO₂), zirconia (ZrO₂), titanium oxide (TiO₂) and iron oxide (FeO).

According to an example embodiment, a size of the at least one of the metal powder and ceramic powder particles may be within a range of 1 nanometer (nm) to 100 micrometers (μm).

According to an example embodiment, the substrate may include at least two stacked unit substrates. Each of the at least two stacked unit substrates may include an inner core layer and an inner circuit formed on a surface of the inner core.

According to an example embodiment, the substrate may include a via-hole penetrating through the substrate. The copper layer may be formed on the sidewalls of the via-hole.

According to an example embodiment, the copper layer may include an outer layer circuit formed on a portion of at least one of an upper surface and a lower surface of the substrate.

According to an example embodiment, an organic solderability preservative (OSP) coating layer may be formed on the outer layer circuit and the conductive film formed on the sidewalls of the via-hole.

According to an example embodiment, the copper layer circuit may include a contact pad.

According to an example embodiment, an electroless nickel immersion gold (ENIG) coating layer may be formed on the outer layer circuit and the conductive film formed on the sidewalls of the via-hole.

According to an example embodiment, the copper layer may include a contact pad.

In an example embodiment, a method of fabricating a PCB may include forming a copper layer over a portion of a substrate. The copper layer may include at least one of a metallic powder and a ceramic powder.

According to an example embodiment, forming the copper layer may include plating the substrate through an electric copper plating process. An electric copper plating solution may be used in the electroplating process that may include the at least one of the metal powder or ceramic powder.

According to an example embodiment, the metal powder may include at least one of cobalt (Co), nickel (Ni), iron (Fe), chromium (Cr), zinc (Zn), nobelium (No), tungsten (W), vanadium (V), manganese (Mn), titanium (Ti), and tin (Sn).

According to an example embodiment, the ceramic powder may include at least one of aluminium oxide (or alumina) (Al₂O₃), silicon carbide (SiC), silicon dioxide (or silica) (SiO₂), zirconia (ZrO₂), titanium oxide (TiO₂) and iron oxide (FeO).

According to an example embodiment, the size of the at least one of the metal powder and ceramic powder particles may be within a range of 1 nanometer (nm) to 100 micrometers (μm).

According to an example embodiment, the substrate may include at least two stacked unit structures. Each of the at least two unit structures may include an inner core layer and an inner layer circuit formed on a surface of the inner core layer.

According to an example embodiment, the substrate may include a via-hole penetrating through the substrate. The method may further include patterning the copper layer so that a portion of the copper layer remains on the sidewalls of the via-holes.

According to an example embodiment, the method may further include patterning the copper layer to form an outer layer circuit on a portion of at least one of an upper surface and a lower surface of the substrate.

According to an example embodiment, a coating layer may be formed on the copper plated film of the outer layer circuit and the sidewalls of the via-hole.

According to an example embodiment, the coating layer may be an OSP coating layer.

According to an example embodiment, the copper layer may include a contact pad.

According to an example embodiment, the coating layer may be an ENIG coating layer.

According to an example embodiment, the copper layer may include a contact pad.

### BRIEF DESCRIPTION OF THE DRAWINGS

Example embodiments will be described with reference to the accompanying drawings.

FIG. 1 is a photograph of cracks formed in a copper plated film in a via-hole in a conventional printed circuit board (PCB).

FIG. 2A is a sectional view of a via-hole in a PCB according to an example embodiment

FIG. 2B is a sectional view of a contact pad in a PCB according to an example embodiment.

FIG. 3 is an example view illustrating operation of the strengthening powder in a copper plated film in a PCB to reduce or prevent the formation and/or spreading of cracks.

FIGS. 4A and 4B are views illustrating a process of forming a stacked substrate according to an example embodiment.

FIGS. 5A through 5F are sectional views illustrating a method of fabricating a PCB including a copper plated film according to an example embodiment.

FIG. 6 is a schematic view illustrating a copper plating apparatus to form a copper plated film according to an example embodiment.

### DESCRIPTION OF EXAMPLE EMBODIMENTS

Example embodiments will now be described more fully with reference to the accompanying drawings. Example embodiments may, however, be embodied in many different forms and should not be construed as being limited to the example embodiments set forth herein. Rather, these example embodiments are provided so that this disclosure will be thorough, and will fully convey the scope to those skilled in the art. Like numbers refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

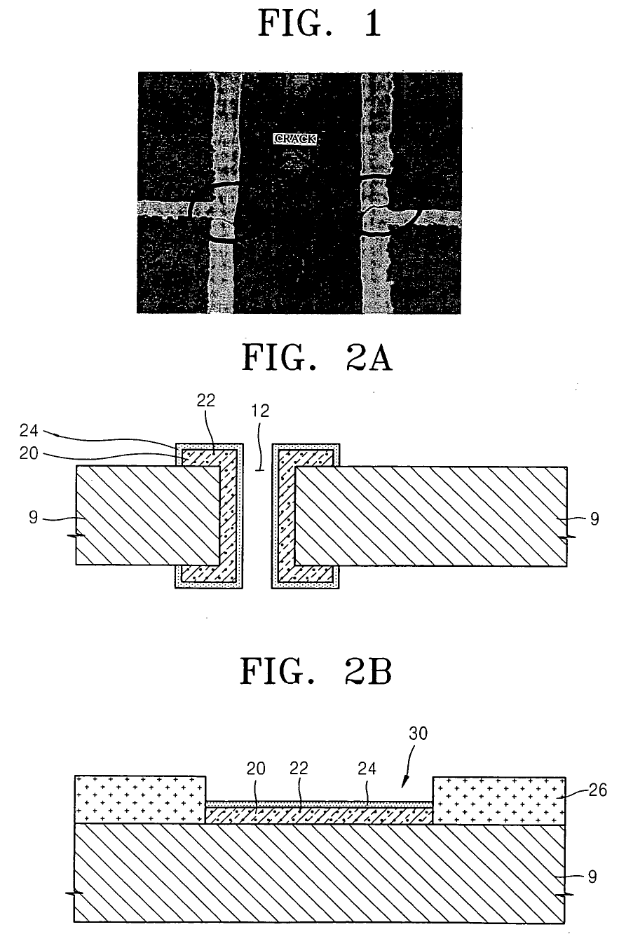

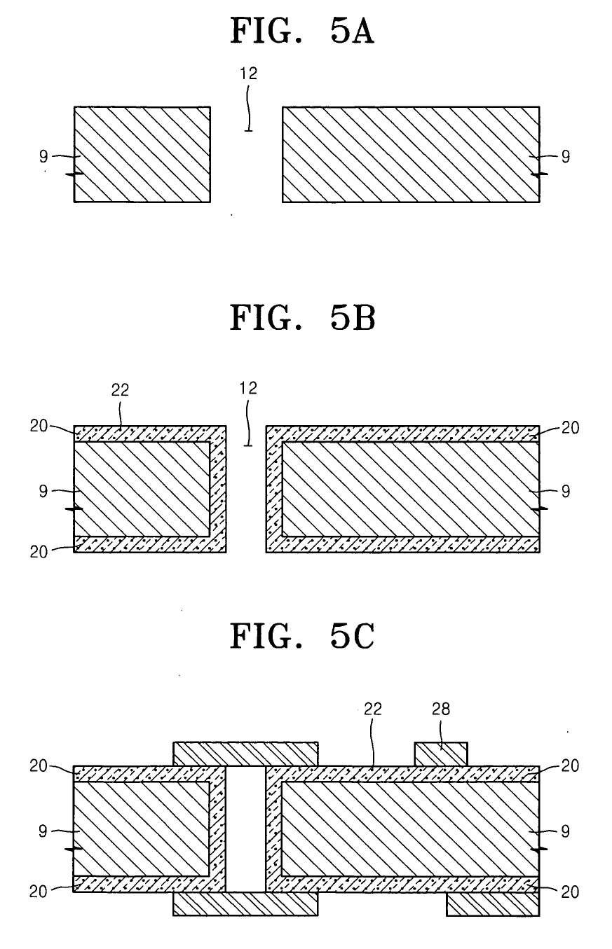

FIG. 2A is a sectional view of a via-hole in a PCB according to an example embodiment. FIG. 2B is a sectional view of a contact pad in a PCB according to an example embodiment. Referring to FIGS. 2A and 2B, a substrate 9 is shown. However, the substrate may be a stacked substrate composed of at least two stacked unit substrates. The details of the stacked substrate have not been shown for the sake of clarity. An example structure of the stacked substrate will be described below with respect to FIGS. 4A-4B.

Referring to FIG. 2A, a substrate 9 may include a via-hole 12 penetrating through the substrate 9. Cooper plated film 20 may be formed on the sidewalls of the via-hole 12 to conduct current. The copper plated film 20 may include strengthening powder 22 which may reduce or prevent the formation and/or spreading of a crack in the copper plated film 20. The strengthening powder 22 may be metal powder, for example, cobalt (Co), nickel (Ni), iron (Fe), chromium (Cr), zinc (Zn), nobelium (No), tungsten (W), vanadium (V), manganese (Mn), titanium (Ti), tin (Sn), or etc. The strengthening power 22 may also be ceramic powder, for example, aluminium oxide (or alumina) (Al₂O₃), silicon carbide (SiC), silicon dioxide (or silica) (SiO₂), zirconia (ZrO₂), titanium oxide (TiO₂), iron oxide (FeO), or etc. An organic solderability preservative (OSP) coating layer 24 may be formed on the copper plated film 20 which may prevent the copper plated film 20 from oxidizing or corroding.

Referring to FIG. 2B, a contact pad 30 may be formed on the outer surface of the substrate 9 as defined by a solder resist pattern 26. The contact pad 30 may include the same copper plated film 20 as on the sidewalls of the via-hole 12. An OSP coating layer 24 may be formed on the copper plated film 20 which may prevent the copper plated film 20 from oxidizing and corroding and may improve the joining force between the contact pad 30 and a solder bump (not shown) that may be formed on the contact pad. By forming a copper plated film 20 containing the strengthening powder 22 is used, the formation and/or spreading of cracks may be reduced or prevented. The solder resist pattern 26 may prevent the formation of a soldering bridge and the oxidization of an exposed circuit when components are mounted on the PCB.

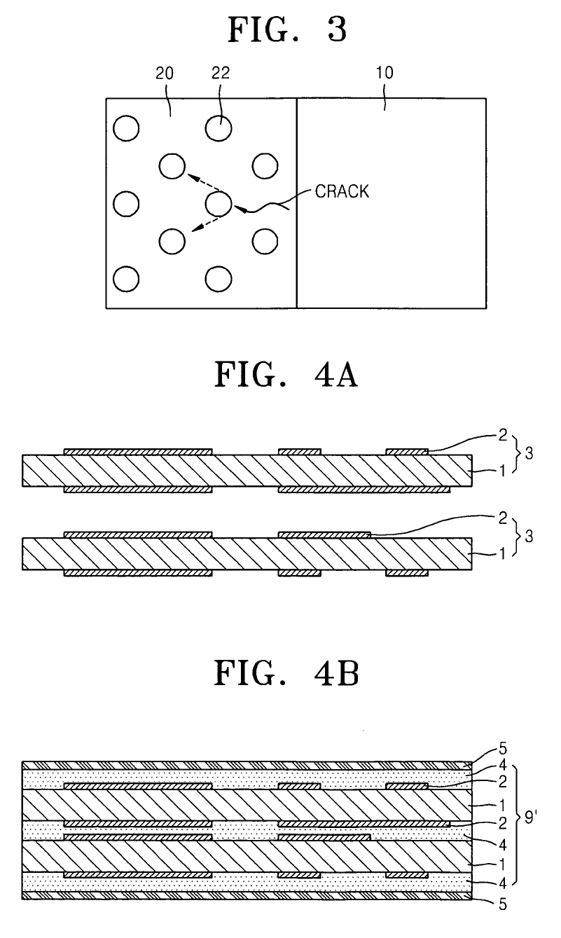

FIG. 3 is an example view illustrating the operation of the strengthening powder to reduce or prevent the formation and/or spreading of cracks. Referring to FIG. 3, if a crack progressing in any direction in the copper plated film 20 meets a particle or particles of the strengthening powder 22, the progression of the crack may be diverted around the particle or particles of the strengthening powder 22, and the crack may be weakened. If the weakened crack meets another particle or particles of the strengthening powder 22 positioned in the path of the crack, the progress of the weakened crack may be stopped from progressing further. For example, if the copper plated film contains the metal powder or ceramic powder, the copper plated film may be reinforced. Thus the formation and/or spreading of cracks in the copper plated film, for example, due to the difference in thermal expansion coefficient between the insulating material and the copper plated film, may be reduced or prevented.

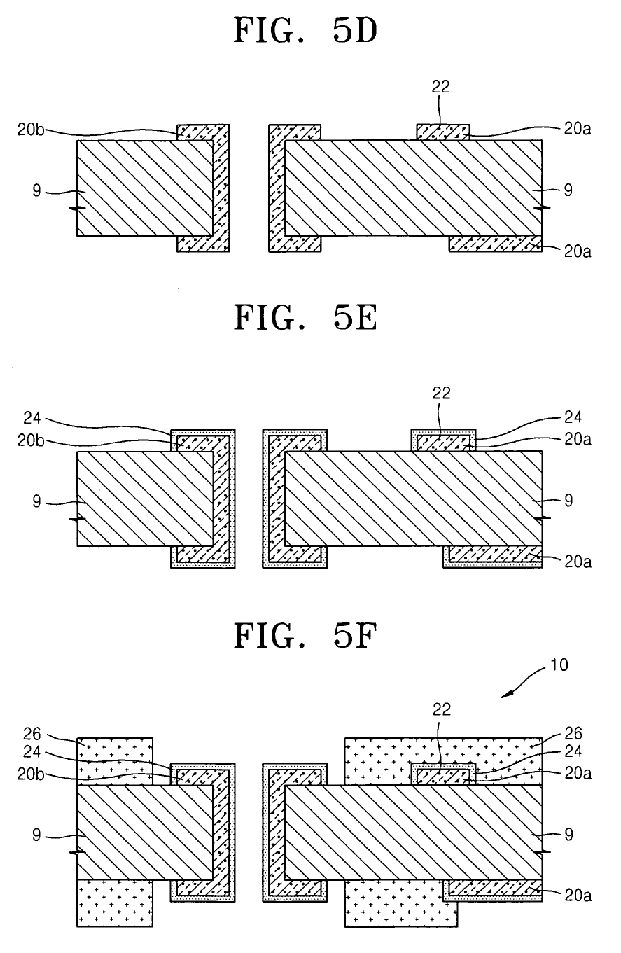

FIGS. 4A and 4B are views illustrating a process of forming a stacked substrate 9′, according to an example embodiment, that may be used in the example embodiments described above in FIGS. 2A-2B or described below in FIGS. 5A-5F.

Referring to FIG. 4A, a unit substrate 3 may include an inner layer core 1 formed of an insulating material. A copper layer may be formed on the surface of the inner layer core 1. The copper layer may be patterned through a photolithography process to form an inner layer circuit 2.

Referring to FIG. 4B, in accordance with the PCB design, at least two unit substrates 3 may be stacked. Middle insulating layers 4 may be formed between the unit substrates 3. The middle insulating layers 4 may be formed to cover the inner layer circuits 2 and the exposed portions of the inner layer core 1. Copper layers 5 may be formed on top and bottom of the stacked substrate 9′.

FIGS. 5A through 5F are sectional views illustrating a method of fabricating a PCB including an reinforced copper plated film according to an example embodiment. FIGS. 5A through 5F schematically illustrate the substrate 9 of FIGS. 2A-2B as a single layer for clarity. However, it will be understood that this process may be applied to a stacked substrate 9′ as shown in FIG. 4B.

Referring to FIG. 5A, a substrate 9 may include a via-hole 12 to electrically connect circuits of the top surface and the bottom surface of the substrate 9. For example, the via-hole 12 may be formed by using a drill or laser.

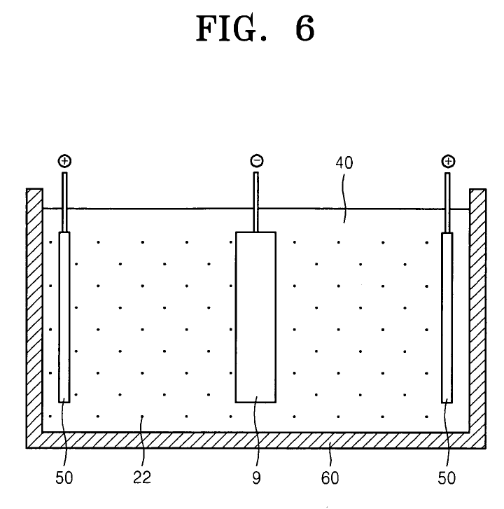

Referring to FIG. 5B, the substrate 9 having the via-hole 12 may be coated with a conductive material to form a plated film, for example, copper plated film 20, on the top and bottom surfaces of the substrate 9 and on the sidewalls of the via-hole 12. As will now be described with reference to FIG. 6, strengthening powder may be included in a copper plating solution 40 used to form the copper plated film 20.

FIG. 6 is a schematic view illustrating a copper plating apparatus that may be used to form a reinforced copper plated film according to an example embodiment. Referring to FIG. 6, the substrate 9 may be connected to a cathode and may be put in a copper plating tank 60 containing the copper plating solution 40. Copper rods 50 connected to an anode may be put in the copper plating tank 60.

The copper plating solution 40 may include the strengthening powder 22. The strengthening powder 22 may be metal powder or ceramic powder. For example, the metal powder may include one or more elements of cobalt (Co), nickel (Ni), iron (Fe), chromium (Cr), zinc (Zn), nobelium (No), tungsten (W), vanadium (V), manganese (Mn), titanium (Ti), tin (Sn), etc. The ceramic powder may include one or more elements of aluminium oxide (or alumina) (Al₂O₃), silicon carbide (SiC), silicon dioxide (or silica) (SiO₂), zirconia (ZrO₂), titanium oxide (TiO₂), iron oxide (FeO), etc. Further, the copper plating solution 40 may include mixed powder of the metal powder and the ceramic powder. The size of the strengthening powder particles 22 may be within a range of 1 nanometers (nm) to 100 micrometers (μm).

If a current is applied across the anode and the cathode, copper ions may be generated and released from the copper rods 50 connected to the anode. The copper ions may dissolve in the copper plating solution 40. The copper ions in the copper plating solution 40, along with the strengthening powder 22, may be deposited on the surface of the substrate 9 connected to the cathode to form the copper plated film 20. The copper plated film 20 therefore includes the strengthening powder 22 of the copper plating solution 40.

Returning to the process of FIGS. 5A-5F and referring to FIG. 5C, a resist pattern 28 may be formed on the copper plated film 20 on the substrate 9. For example, a dry resist film may be thermal-pressed on one or both sides of the substrate 9. A master film (not shown) where the circuit may be subsequently formed may be used to expose and develop the dry resist film to form the resist pattern 28.

Referring to FIG. 5D, the copper plated film 20 on the surface of the substrate 9 may be etched by an etchant, using the resist pattern 28 as a mask. The resist pattern 28 may be removed from the surface of the substrate 9 leaving in place the copper plated film 20a and 20b on the upper and lower surfaces of the substrate 9 on the sidewalls of the via-hole 12. The copper plated film on the upper and lower surfaces of the substrate may be referred to as an outer layer circuit 20a. A portion of the outer layer circuit 20a may be formed to include a contact pad on which a joining structure (not shown), for example, a solder bump, may be formed.

Referring to FIG. 5E, an organic solderability preservative (OSP) coating layer 24 may be formed on the outer layer circuit 20a and the copper plated film 20b formed on the sidewalls of the via-hole 12. The OSP coating layer 24 may prevent the copper plated film 20a and 20b from being oxidized or corroded. The OSP coating layer 24 may also improve the joining force of the solder bump on the contact pad.

Referring to FIG. 5F, a solder resist pattern 26 may be formed on the surface of the substrate 9. The solder resist pattern 26 may prevent the formation of a soldering bridge and the oxidization of an exposed circuit when components are mounted on the PCB 10.

In accordance with an example embodiment, because the copper plated film may include a strengthening powder, the integrity of the copper plated film may be reinforced. As a result, the formation and/or spreading of cracks in the copper plated film in a via-hole and/or a contact pad may be reduced or prevented, and thus the reliability on the PCB may be improved.

While example embodiments have been particularly shown and described, it will be understood by those of ordinary skill in the art that various changes in form and details may be made therein without departing from the spirit and scope of the present invention.

What is claimed is:

1. A PCB (printed circuit board), comprising:
a substrate;
a copper layer pattern formed over a portion of the substrate, the copper layer pattern including at least one of a metallic powder and a ceramic powder.

2. The PCB of claim 1, wherein the metal powder includes at least one of cobalt (Co), nickel (Ni), iron (Fe), chromium (Cr), zinc (Zn), nobelium (No), tungsten (W), vanadium (V), manganese (Mn), titanium (Ti), and tin (Sn).

3. The PCB of claim 1, wherein the ceramic powder includes at least one of aluminium oxide (or alumina) (Al₂O₃), silicon carbide (SiC), silicon dioxide (or silica) (SiO₂), zirconia (ZrO₂), titanium oxide (TiO₂) and iron oxide (FeO).

4. The PCB of claim 1, wherein a size of the at least one of the metal powder and ceramic powder particles are within a range of 1 nanometer (nm) to 100 micrometers (μm).

5. The PCB of claim 1, wherein the substrate includes at least two stacked unit substrates, each of the at least two stacked unit substrates includes an inner core layer and an inner layer circuit formed on a surface of the inner core layer.

6. The PCB of claim 1, wherein the substrate includes a via-hole penetrating through the substrate, and the copper layer pattern is formed on the sidewalls of the via-hole.

7. The PCB of claim 1, wherein the copper layer pattern includes an outer layer circuit formed on a portion of at least one of an upper surface and a lower surface of the substrate.

8. The PCB of claim 1, further comprising:
an organic solderability preservative (OSP) coating layer on the copper layer pattern.

9. The PCB of claim 8, wherein the copper layer pattern includes a contact pad.

10. The PCB of claim 1, further comprising:
an electroless nickel immersion gold (ENIG) coating layer on the copper layer pattern.

11. The PCB of claim 10, wherein the copper layer pattern includes a contact pad.

12. A method of fabricating a PCB (printed circuit board), comprising:
forming a copper layer over a portion of a substrate, the copper layer including at least one of a metallic powder and a ceramic powder.

13. The method of claim 12, wherein the forming of the copper layer includes plating the substrate through an electric copper plating process, and wherein an electric copper plating solution used in the electroplating process includes the at least one of the metal powder or ceramic powder.

14. The method of claim 12, wherein the metal powder includes at least one of cobalt (Co), nickel (Ni), iron (Fe), chromium (Cr), zinc (Zn), nobelium (No), tungsten (W), vanadium (V), manganese (Mn), titanium (Ti), and tin (Sn).

15. The method of claim 12, wherein the ceramic powder includes at least one of aluminium oxide (or alumina) (Al₂O₃), silicon carbide (SiC), silicon dioxide (or silica) (SiO₂), zirconia (ZrO₂), titanium oxide (TiO₂) and iron oxide (FeO).

16. The method of claim 12, wherein the size of the at least one of the metal powder and ceramic powder particles are within a range of 1 nanometer (nm) to 100 micrometers (μm).

17. The method of claim 12, wherein the substrate includes at least two stacked unit substrates, and each of the at least two stacked unit substrates includes an inner core layer and an inner layer circuit formed on a surface of the inner core layer.

18. The method of claim 12, wherein the substrate includes a via-hole penetrating through the substrate, further comprising:
patterning the copper layer so that a portion of the copper layer remains on the sidewalls of the via-holes.

19. The method of claim 12, further comprising:
patterning the copper layer to form an outer layer circuit on a portion of at least one of an upper surface and a lower surface of the substrate.

20. The method of claim 12, further comprising:
forming a coating layer on the copper layer.

21. The method of claim 20, wherein the coating layer is an organic solderability preservative (OSP) coating layer

22. The method of claim 21, wherein the copper layer includes a contact pad.

23. The method of claim 20, wherein the coating layer is an electroless nickel immersion gold (ENIG) coating layer.

24. The method of claim 23, wherein the copper layer includes a contact pad.
